(19) United States
(12) Patent Application Publication
(10) Pub. No.: US 2026/0344254 A1
(43) Pub. Date: Oct. 29, 2026

(54) DISPLAY PANEL AND DISPLAY DEVICE INCLUDING THE SAME

(71) Applicant: LG Display Co., Ltd., Seoul (KR)

(72) Inventor: Mingyeong CHOI, Paju-si (KR)

(73) Assignee: LG Display Co., Ltd., Seoul (KR)

(21) Appl. No.: 19/547,214

(22) Filed: Feb. 23, 2026

(30) Foreign Application Priority Data
Apr. 24, 2025 (KR) 10-2025-0053985

(51) Int. Cl. H10K 59/80; H05K 1/189

(52) U.S. Cl. CPC H10K 59/8722; H05K 1/189; H05K 2201/10128

(57) ABSTRACT

A display panel and a display device including the display panel is disclosed. The display panel is configured to prevent occurrence of an air trap when a flexible printed circuit board is pressed and attached to a support member. An adhesive film is disposed between the flexible printed circuit board and the support member, the adhesive film having at least one air path formed on one surface thereof to be attached to the support member. The air path discharges air located between the flexible printed circuit board and the support member during pressing and attaching of the flexible printed circuit board to the support member.

### CROSS-REFERENCE TO RELATED APPLICATION

The present application claims priority to Korean Patent Application No. 10-2025-0053985, filed on Apr. 24, 2025, the entire contents of which are incorporated herein for all purposes by this reference.

### BACKGROUND

### Technical Field

The present specification relates to a display panel and a display device including the display panel, and more specifically, is to provide a display panel in which it is possible to prevent the occurrence of an air trap when a flexible printed circuit board is pressed and attached to a support member.

### DESCRIPTION OF THE RELATED ART

Display devices have been applied to televisions, monitors, smartphones, tablet PCs, laptops, wearable devices, and the like in a wide variety of forms and manners. Among the display devices used in various forms and manners, there is an organic light-emitting display (OLED) device.

The organic light-emitting display device is equipped with self-emissive elements, in which the elements themselves become light-emitting bodies themselves, so it does not require a separate light source, which allows it to be bent or to be implemented in display devices of various designs.

Additionally, the organic light-emitting display device enables the manufacturing of thinner display devices than a liquid crystal display (LCD) device, and enables the manufacturing of display devices for realizing a high-definition video as it has the advantages of excellent color implementation, viewing angle and contrast ratio, and fast response speed, and thus the range of its use is gradually increasing.

As the technology of these display devices advances, the thickness of the flexible printed circuit board (FPCB) constituting the display panel is also gradually becoming thinner.

### BRIEF SUMMARY

As the thickness of a flexible printed circuit board decreases and the width of a portion (e.g., tail portion) of the flexible printed circuit board increases, adhesive strength when attaching the flexible printed circuit board to a support member may be reduced. Additionally, when a protective film attached to a portion of the flexible printed circuit board is delaminated, bubbles may occur between the portion of the flexible printed circuit board and the support member.

In view of the above, a display panel and a display device including the display panel are provided in which bubbles that may occur between the portion of the flexible printed circuit board and the support member during removal of the protective film can be reduced or removed.

Various embodiments of the present specification a display panel and a display device including the display panel, in which it is possible to remove air occurred between a portion of the flexible printed circuit board and the support member when the flexible printed circuit board is pressed and attached to the support member.

Various embodiments of the present specification an adhesive film disposed between the support member and the flexible printed circuit board and having at least one air path formed to allow air to escape when the flexible printed circuit board is pressed and attached to the support member.

The technical benefits of the present specification are not limited to the ones described above, and other benefits and advantages of the present specification which are not mentioned can be understood from the following description, and will be more clearly understood from the embodiments of the present specification. Furthermore, it will be readily appreciated that the objects and advantages of the present specification can be realized by the means presented in the claims, and combinations thereof.

According to an embodiment of the present specification, there is provided a display panel including an adhesive film, which is disposed between a support member stacked toward the rear surface of the display panel and a flexible printed circuit board having a portion bent toward the rear surface of the support member, and which is attached to one surface of the flexible printed circuit board so that the bent flexible printed circuit board is pressed and attached to the support member.

Additionally, according to an embodiment of the present specification, there is provided a display panel including an adhesive film on which a plurality of air paths are formed in a direction horizontal to the tail portion direction of the flexible printed circuit board.

Additionally, according to an embodiment of the present specification, there is provided a display panel including an adhesive film on which a plurality of air paths are formed in a direction vertical to the tail portion direction of the flexible printed circuit board.

Additionally, according to an embodiment of the present specification, there is provided a display panel including an adhesive film on which a plurality of air paths are formed in a direction horizontal to the tail portion direction of the flexible printed circuit board, and a plurality of air paths are formed in a direction vertical to the tail portion direction of the flexible printed circuit board.

According to embodiments of the present specification, by attaching the flexible printed circuit board to the support member using an adhesive film with at least one air path formed on one surface thereof attached to the support member so that air is discharged during a process of pressing and attaching the flexible printed circuit board to the support member, air traps can be effectively eliminated, which may occur when removing the liner.

Additionally, according to the present specification, by attaching the flexible printed circuit board to the support member through an adhesive film on which a plurality of air paths are formed in a direction horizontal to the tail portion direction of the flexible printed circuit board, air traps can be effectively eliminated, which are formed along the horizontal direction.

Additionally, according to the present specification, by attaching the flexible printed circuit board to the support member through an adhesive film on which a plurality of air paths are formed in a direction vertical to the tail portion direction of the flexible printed circuit board, air traps can be effectively eliminated, which are formed along the vertical direction.

Additionally, according to the present specification, by attaching the flexible printed circuit board to the support member through an adhesive film on which a plurality of air paths are formed in directions horizontal and vertical to the tail portion direction of the flexible printed circuit board, air traps can be effectively eliminated, which are in a dispersed state.

Additionally, according to the present specification, by forming a plurality of air paths on the adhesive film, it is possible to achieve the weight lightening and production cost reduction of the display panel.

The present specification may have other effects besides the aforementioned ones, which are clearly recognizable to a person skilled in the art from the description below.

### BRIEF DESCRIPTION OF THE SEVERAL VIEWS OF THE DRAWINGS

FIG. 1 is a plan view illustrating a display device according to an embodiment of the present specification.

FIG. 2A is an illustrative view illustrating a state before a flexible printed circuit board is bent according to an embodiment of the present specification.

FIG. 2B is an illustrative view illustrating a process in which a portion of a flexible printed circuit board is bent by a first pusher according to an embodiment of the present specification.

FIG. 3A is an illustrative view illustrating a state in which a portion of a flexible printed circuit board is bent onto a support member according to an embodiment of the present specification.

FIG. 3B is an illustrative view illustrating a state in which a protective film attached to a portion of a flexible printed circuit board is removed according to an embodiment of the present specification.

FIG. 3C is an illustrative view illustrating a state in which a portion of a flexible printed circuit board is pressed and attached to a support member according to an embodiment of the present specification.

FIG. 4A is an illustrative view showing one surface of a flexible printed circuit board according to an embodiment of the present specification.

FIG. 4B is an illustrative view illustrating a state in which an adhesive film is attached to the other surface of the flexible printed circuit board according to an embodiment of the present specification.

FIG. 5 is an illustrative view illustrating a state in which a flexible printed circuit board and a support member are attached to each other through an adhesive film according to an embodiment of the present specification.

FIG. 6A is a first illustrative view in which an air path is formed in an adhesive film according to an embodiment of the present specification.

FIG. 6B is a second illustrative view in which an air path is formed in an adhesive film according to an embodiment of the present specification.

FIG. 6C is a third illustrative view in which an air path is formed in an adhesive film according to an embodiment of the present specification.

### DETAILED DESCRIPTION

Advantages and features of the present specification, and a method of achieving the advantages and features will become apparent when referring to the following embodiments described later in detail together with the accompanying drawings. However, the present specification is not limited to the embodiments as disclosed below, but may be embodied in various different forms. Thus, these embodiments are set forth only to make the present specification complete, and to completely inform the scope of the present specification to those of ordinary skill in the technical field to which the present specification belongs.

In assigning reference numerals to the components shown in the drawings in this specification, it should be noted that the same components are given the same reference numerals as far as possible, even if they are shown in different drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the detailed description, like reference symbols refer to like components. Further, in describing the present specification, if it is determined that a detailed description of a related known technology may unnecessarily obscure the gist of the present specification, the detailed description thereof will be omitted. When the terms “comprise”, “include”, “have”, “be configured with”, “be comprised of”, and the like are used in the present specification, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, and “next to”, one or more other elements may be interposed between the two elements unless “just”, “directly”, or “close” is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

In describing a temporal relationship, for example, when the temporal order is described as “after”, “subsequent”, “next”, and “before”, the case which is not continuous may also be included unless the term “just” or “directly” is used.

When describing the flow relationship of a signal, for example, in a case where ‘a signal is transmitted from node A to node B’, it may include a case where a signal is transmitted from node A to node B via another node, unless the term ‘immediately’ or ‘directly’ is used.

It will be understood that, although the term “first”, “second”, or the like may be used herein to describe various elements, these elements should not be limited by this kind of terminology. These terms are merely used to distinguish one element from another element. So, a first element referred to in the following description may represent a second element, without departing from the scope of the technical idea of the present specification.

The individual features of the various embodiments of the present specification may be coupled or combined with each other in part or in whole to be interconnected and operated in a variety of technical ways, and each embodiment may be implemented independently of each other or implemented together in an associative relationship.

The present disclosure addresses a manufacturing defect that occurs when a flexible printed circuit board tail portion is bent and press attached to a rear support member of a display panel. As the flexible printed circuit board becomes thinner and the tail portion becomes wider, conventional pressure sensitive adhesive bonding forms a sealed interface during liner removal and traps air between the flexible printed circuit board and the support plate. The trapped air produces bubbles that degrade adhesion reliability, visual quality, and potentially electrical performance.

To address this condition, an adhesive film is positioned between the bent portion of the flexible printed circuit board and the support member and includes one or more air discharge paths. During the pressing attachment step, air escapes through these paths rather than remaining within the bonding interface, allowing full surface contact without vacuum processing or additional rolling operations. The vent structure operates during the lamination event rather than functioning only as a textured adhesive surface.

Additional configurations include arranging the air paths horizontally, vertically, or in a combined pattern relative to the flexible printed circuit board tail direction, optionally forming channels on one or both adhesive surfaces, and placing the vented adhesive only in the bent tail region where air trapping occurs. The disclosed subject matter therefore relates to a directionally arranged air vent adhesive structure adapted for bent tail flexible printed circuit board attachment in display modules to reduce liner removal air trapping.

In describing the present embodiment, descriptions of components which are the same as or corresponding to those of the previous embodiments will be omitted. Hereinafter, a display device according to the present embodiment will be described with reference to the drawings.

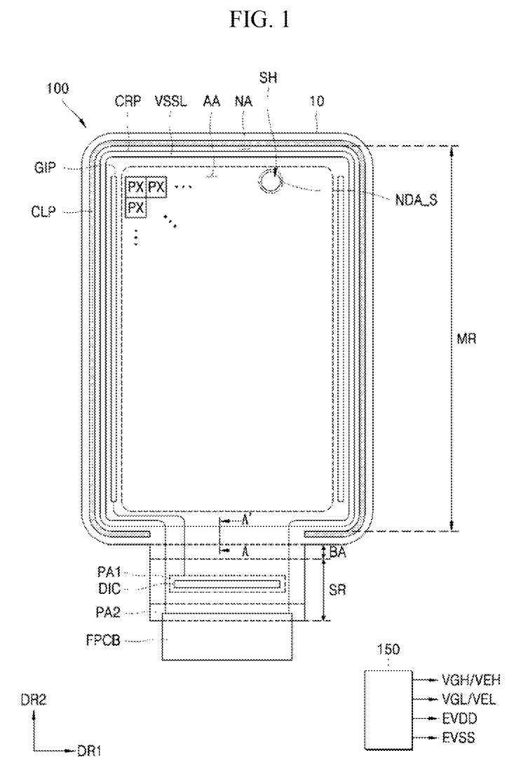

FIG. 1 is a plan view illustrating a display device according to an embodiment of the present specification.

Referring to FIG. 1, the display device 100 according to an embodiment of the present specification may include a display panel 10.

According to an embodiment, the display panel 10 may include a plurality of regions. The plurality of regions may include a main region MR, a bending region BA, and a sub-region SR.

According to an embodiment, the main region MR may include an active area AA and a non-active area NA. The bending region BA may be a region bent in a thickness direction from the main region MR. The sub-region SR may be a region connected with the bending region BA to be opposite the main region MR.

According to an embodiment, the active area AA may be an area in which a picture image is displayed. The non-active area NA may be an area other than the active area AA. Although not shown, the active area AA may have a pixel array formed inside.

According to an embodiment, one or more non-active areas NA in which a picture image is not displayed may include a data driving part DIC and a clad portion CLP serving as a dam, and may be provided on one side of the active area AA. For example, the non-active area NA may be adjacent to one or more sides of the active area AA.

According to an embodiment, the non-active area NA may be located outside the rectangular active area AA to surround it. However, it should be understood that the shapes of the active area AA and the adjacent arrangement of the non-active area NA and the active area AA are not specifically limited to the illustrative display device 100 shown in FIG. 1. The active area AA and the non-active area NA may be any shape of the display device 100. Non-limiting examples of such shapes may include a pentagon, a hexagon, a circle, an oval shape, and the like, and the embodiment of the present specification is not limited to this.

According to an embodiment, in the non-active area NA, a crack detection pattern CRP may be disposed in a form surrounding three sides of the active area AA. The crack detection pattern CRP may be used to detect a state in which a crack has occurred in the display panel 10.

According to an embodiment, between the crack detection pattern CRP and the active area AA, a low-potential power line VSSL may be disposed in a form surrounding three sides of the active area AA.

According to an embodiment, in the non-active area NA at both side ends of the active area AA, gate driving parts GIPs may be respectively disposed in the second direction DR2. The gate driving part GIP supplies a gate signal (or scan signal) to the active area AA.

According to an embodiment, the active area AA may include a second non-active area NA_S in which a camera area SH is disposed. In the camera area SH, a camera may be disposed internally.

According to an embodiment, the bending region BA may be disposed between the main region MR and the sub-region SR, and may connect the main region MR with the sub-region SR. The width of the bending region BA in the first direction DR1 may be smaller than the width of the main region MR in the first direction DR1 and may be equal to the width of the sub-region SR in the first direction DR1.

Although not shown, the display device 100 may further include a plurality of lines extending from the sub-region SR to the main region MR through the bending region BA. The plurality of lines may include a first line to which a first voltage is applied, a second line to which a second voltage is applied, and a dummy line which is disposed between the first line and the second line and to which a third voltage is applied.

The display device 100 may further include the data driving part DIC disposed in the sub-region SR, and the first line and the second line may each be connected to the data driving part DIC.

According to an embodiment, the active area AA may include a plurality of pixels PX. One pixel PX may include a plurality of sub-pixels. Each of the plurality of sub-pixels may include a light-emitting element. The light-emitting element may be an inorganic light-emitting element or an organic light-emitting element, and the embodiments of the present specification are not limited to this. The plurality of sub-pixels may display colors such as red R, green G, blue B, white W, and the like. The plurality of sub-pixels may be disposed in the active area AA, and each of them may include one or more transistors. At least one transistor and a light-emitting element may be connected with each other.

Additionally, the pixel and the sub-pixel may each be associated with a pixel circuit including one or more TFTs manufactured on the display panel 10 of the display device 100. Each pixel circuit may be electrically connected to a gate line and a data line to communicate with one or more driving circuits, for example, the gate driving part GIP and the data driving part DIC located in the non-active area NA of the display device 100.

According to an embodiment, the sub-region SR may include a first pad area PA1 and a second pad area PA2. In the first pad area PA1, the data driving part DIC may be disposed, while, in the second pad area PA2, a flexible printed circuit board FPCB may be disposed.

According to an embodiment, the one or more driving circuits may be implemented with TFTs configured in the non-active area NA. For example, the gate driving part GIP may be implemented using a plurality of TFTs on the display panel 10 of the display device 100. Non-limiting examples of circuits that may be implemented with TFTs of the display panel 10 may include inverter circuits, multiplexers, and electro static discharge (ESD) circuits, but the embodiments of the present specification are not limited to this.

According to an embodiment, some driving circuits may be provided as an integrated circuit IC chip, and may be mounted in the non-active area NA of the display device 100 using a chip-on-glass (COG) or other similar method. Alternatively, some of the driving circuits may be mounted on another substrate, and be coupled to connection interfaces (pads/bumps, pins) disposed in the non-active area NA using flexible printed circuit board (FPCB), chip-on-film (COF), tape-carrier-package (TCP), or other suitable technologies.

In embodiments of the present specification, at least two different types of TFTs are used in a TFT substrate for a display. The types of TFTs employed in some pixel circuits and some driving circuits may be variable depending on the requirements of the display.

For example, a pixel circuit may be implemented with a TFT having an oxide active layer (oxide TFT), and a driving circuit may be implemented with a TFT having a low-temperature polycrystalline silicon active layer (LTPS TFT) and a TFT having an oxide active layer. Unlike LTPS TFTs, oxide TFTs do not undergo pixel-to-pixel threshold voltage (Vth) variation problems. A uniform threshold voltage (Vth) may also be obtained in an array of pixel circuits for a display. The issue of uniformity of threshold voltage (Vth) between TFTs implementing the driving circuit will have less direct impact on the uniformity of luminance of pixels.

By using driver circuits on a substrate, which are implemented with LTPS TFTs, signals and data can be provided to pixels at a higher clock rate than the case where all TFTs in a TFT panel are formed with oxide TFTs. Therefore, it is possible to provide a display capable of operating at a high speed without stains such as mura. For example, it is possible to make selection between oxide TFTs and LTPS TFTs and use the selected ones according to each of advantages of oxide TFT and LTPS TFT, which is combined with the design of the TFT panel.

According to an embodiment, each pixel PX may be supplied with a gate signal from the gate driving part GIP through the gate line, and be supplied with a data signal from the data driving part DIC through the data line. The power supply unit 150 may supply power required for driving to each of the plurality of pixels PX. For example, each pixel PX may be supplied with a high-potential driving voltage EVDD and a low-potential driving voltage EVSS from the power supply unit 150, but the embodiments of the present specification are not limited to this.

Additionally, the plurality of pixels PX may further include a power line to be supplied with a bias voltage and an initialization voltage.

According to an embodiment, the power supply unit 150 may generate DC power required for driving the pixel array of the display panel 10 and the display panel driving unit, with the use of a DC-DC converter. The DC-DC converter may include a charge pump, a regulator, a buck converter, a boost converter, or the like, but the embodiments of the present specification are not limited to this. The power supply unit 150 may receive a DC input voltage applied from the host system to generate DC voltages such as a gate-on voltage VGL, VEL, a gate-off voltage VGH, VEH, a high-potential driving voltage EVDD, a low-potential driving voltage EVSS, and the like. The gate-on voltages VGL, VEL and the gate-off voltages VGH, VEH may be supplied to the level shifter and the gate driving part GIP. And the high-potential driving voltage EVDD and the low-potential driving voltage EVSS may be commonly supplied to the pixels PX.

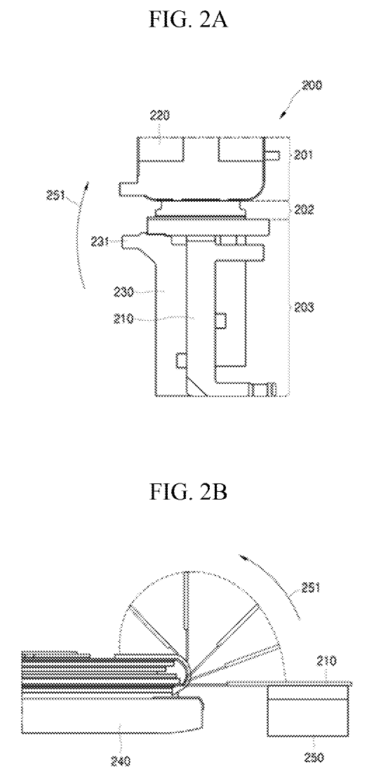

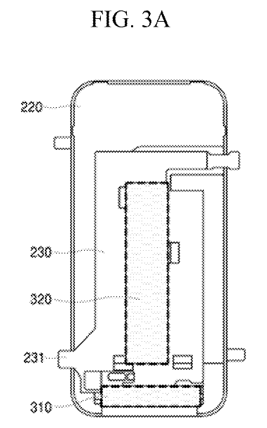

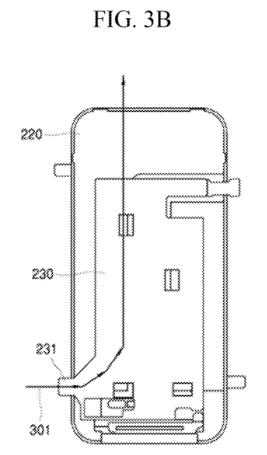

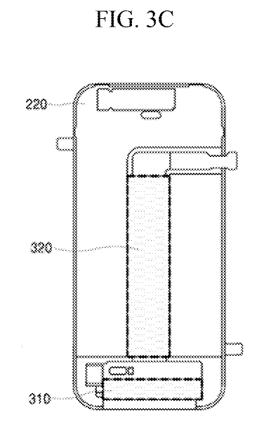

FIGS. 2 and 3 are illustrative views illustrating a process state in which a flexible printed circuit board is bent, and then pressed and attached to a support member according to an embodiment of the present specification.

More specifically, FIG. 2A is an illustrative view illustrating a state before a flexible printed circuit board is bent according to an embodiment of the present specification. FIG. 2B is an illustrative view illustrating a process in which a portion of a flexible printed circuit board is bent by a first pusher according to an embodiment of the present specification. FIG. 3A is an illustrative view illustrating a state in which a portion of a flexible printed circuit board is bent onto a support member according to an embodiment of the present specification. FIG. 3B is an illustrative view illustrating a state in which a protective film attached to a portion of a flexible printed circuit board is removed according to an embodiment of the present specification. FIG. 3C is an illustrative view illustrating a state in which a portion of a flexible printed circuit board is pressed and attached to a support member according to an embodiment of the present specification.

Referring to FIGS. 2A and 2B, the flexible printed circuit board 200 may include a first region 201 disposed in the main region MR of the display panel 10, a second region 202 to be bent, and a third region 203 that is bent and pressed toward the support member 220 of the display panel 10.

With respect to FIG. 2A, the first region 201 is disposed in the lower portion of the support member 220. And, based on FIG. 2B, a first pusher may be disposed in the lower portion of the third region 203 of the flexible printed circuit board 200.

The third region 203 of the flexible printed circuit board 200 is bent (i.e., bent upward) by the operation 251 (i.e., moving counterclockwise) of the first pusher 250, and eventually the third region 203 is attached to the upper portion of the support member 220.

The support member 220 may be disposed in the lower portion of the display panel to supplement the rigidity of the display panel and provide a heat dissipation function. The support member 220 may be formed to have a certain strength and thickness to supplement the rigidity of the display panel. The support member 220 may be made of polyethylene terephthalate (PET), polycarbonate (PC), polyimide (PI), and the like. Additionally, various cushion plates (not shown) may be disposed in the lower portion of the support member 220.

A protective film 230 is attached to the lower surface of the third region 203 of the flexible printed circuit board 200, and this protective film 230 can protect the third region 203 from foreign substance adsorption or the like. This protective film 230 may be removed from the third region 203 of the flexible printed circuit board 200 through a liner 231.

As described above, the process of bending the some regions of the flexible printed circuit board 200 is a process of attaching the some regions of the flexible printed circuit board 200 placed on the stage 240 to the top surface of the support member 220 through the first pusher 250.

Referring to FIGS. 3A, 3B, and 3C, the some regions (e.g., the first region 310 and the second region 320) of the flexible printed circuit board 200 are attached to the top surface of the support member 220, and a protective film 230 is attached to the top surface of the some regions (e.g., the first region 310 and the second region 320) of the flexible printed circuit board 200.

When the some regions (e.g., the first region 310 and the second region 320) of the flexible printed circuit board 200 are bent and attached to the top surface of the support member 220 by an adhesive film, the some regions of the flexible printed circuit board 200 may be pressed and attached by a second pusher (not shown).

Thereafter, the protective film 230 is removed in the upward direction 301 by the liner 231, and then, the some regions (e.g., the first region 310 and the second region 320) of the flexible printed circuit board 200 is once again pressed and attached to the support member 220 through a third pusher (not shown).

As technology advances, the thickness of a display device gradually decreases, and accordingly, the thickness of the flexible printed circuit board 200 is also gradually decreasing. However, as the thickness of the flexible printed circuit board 200 decreases and the width of its portion (e.g., the tail portion) increases, the possibility increases that bubbles will be generated in the tail portion when the protective film 230 is delaminated.

As described above, with the increasing width of the portion of the flexible printed circuit board 200 (e.g., the tail portion), the probability of occurrence of an air trap is increasing. This air trap may occur because the adhesive force decreases as the thickness decreases.

Therefore, there is a need to dispose an adhesive film at a location where one surface of the portion of the flexible printed circuit board 200 (e.g., a tail portion) is in contact with the support member 220, and to form an air path on one surface of the adhesive film, through which air can escape from a section thereof where the air trap occurs.

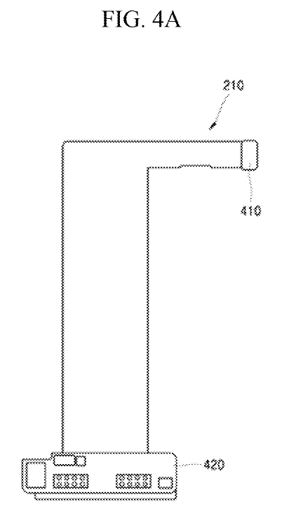

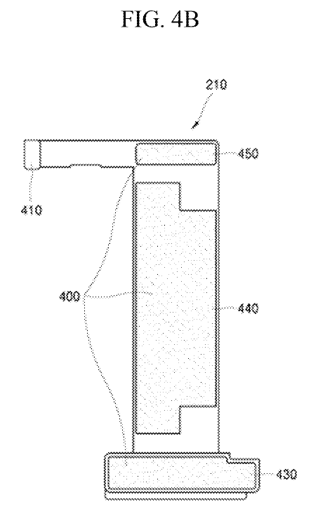

FIG. 4A is an illustrative view showing one surface of a flexible printed circuit board according to an embodiment of the present specification. FIG. 4B is an illustrative view illustrating a state in which an adhesive film is attached to the other surface of the flexible printed circuit board according to an embodiment of the present specification.

Referring to FIG. 4A, a connector 410 is disposed in a portion (e.g., TOP PSA tail portion) of the flexible printed circuit board 200, and a terminal may be formed in a portion 420 (e.g., TOP PSA body portion) of the flexible printed circuit board 200 to be electrically connected to a substrate.

Unlike the conventional hard PCB, the flexible printed circuit board 200 is an electrical circuit board prepared to have flexible characteristics, and is used in various fields such as mobile devices, automobiles, medical devices, and the like. The flexible printed circuit board 200 is thin and flexible, thereby increasing space utilization and contributing to miniaturization and weight reduction of products.

Referring to FIG. 4B, on the other surface of the flexible printed circuit board 200, an adhesive film 400 may be disposed which brings the flexible printed circuit board into close contact with the support member 220 stacked toward the rear surface of the display panel. For example, a first adhesive film 430 may be disposed on the other surface of a portion of the flexible printed circuit board 200 (e.g., TOP PSA body portion); a second adhesive film 440 may be disposed on the other surface of a portion of the flexible printed circuit board 200 (e.g., TOP PSA tail portion); and a third adhesive film 450 may be disposed on the other surface of a portion of the flexible printed circuit board 200 (e.g., TOP PSA tail portion).

Through these adhesive films 430, 440, and 450, the flexible printed circuit board 200 is in close contact with the support member 220.

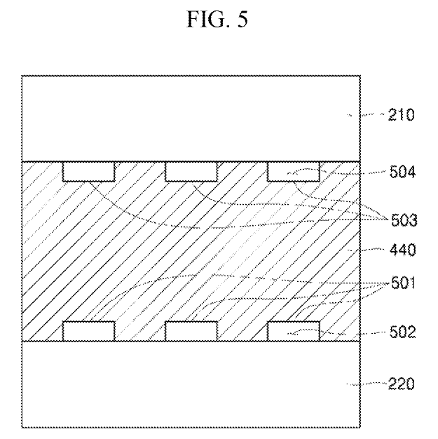

FIG. 5 is an illustrative view illustrating a state in which a flexible printed circuit board and a support member are attached to each other through an adhesive film according to an embodiment of the present specification.

Referring to FIG. 5, the adhesive films 430, 440, and 450 are disposed between the portion 210 of the flexible printed circuit board 200 and the support member 220 to closely adhere the portion 210 of the flexible printed circuit board 200 and the support member 220 to each other. For example, the second adhesive film 440 is disposed between the portion 210 (e.g., TOP PSA tail) of the flexible printed circuit board 200 and the support member 220 to closely adhere the portion 210 of the flexible printed circuit board 200 and the support member 220 to each other. At least one air path 501, 503 may be formed in this second adhesive film 440 to allow air to escape through an air channel 502, 504 by a pusher (e.g., a second pusher or a third pusher).

For example, at least one air path 501 may be formed on one surface of the second adhesive film 440 so that the air existing between the second adhesive film and the support member 220 can escape. The shape of this air path 501 may be freely designed.

Likewise, at least one air path 503 may be formed on the other surface of the second adhesive film 440 so that air existing between the second adhesive film and the portion 210 of the flexible printed circuit board 200 can escape.

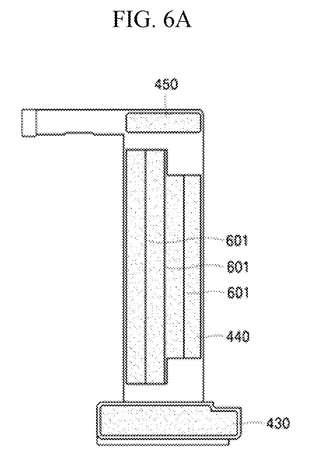

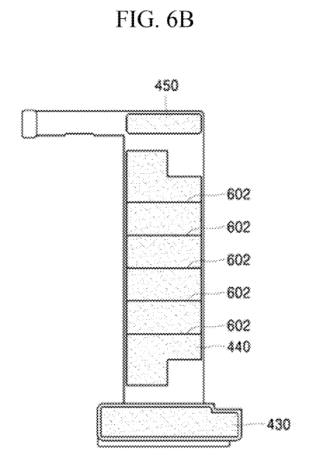

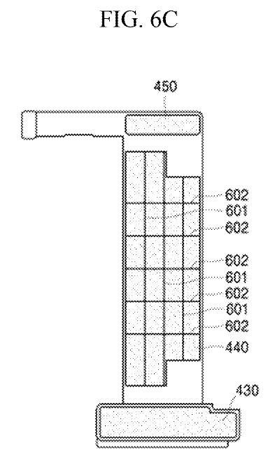

FIG. 6A is a first illustrative view in which an air path is formed in an adhesive film according to an embodiment of the present specification. FIG. 6B is a second illustrative view in which an air path is formed in an adhesive film according to an embodiment of the present specification. FIG. 6C is a third illustrative view in which an air path is formed in an adhesive film according to an embodiment of the present specification.

Referring to FIG. 6A, on the other surface of the flexible printed circuit board 200, an adhesive film 430, 440, 450 may be disposed which brings the flexible printed circuit board into close contact with the support member 220 stacked toward the rear surface of the display panel. For example, a first adhesive film 430 may be disposed on the other surface of a portion of the flexible printed circuit board 200 (e.g., TOP PSA body portion); a second adhesive film 440 may be disposed on the other surface of a portion of the flexible printed circuit board 200 (e.g., TOP PSA tail portion); and a third adhesive film 450 may be disposed on the other surface of a portion of the flexible printed circuit board 200 (e.g., TOP PSA tail portion).

According to an embodiment, on the top surface of the second adhesive film 440 to be brought into close contact with the support member 220, at least one air path 601 may be formed in a vertical direction, through which air escapes. For example, on the top surface of the second adhesive film 440, a plurality of air paths 601 may be formed, and the air paths 601 may be formed to be spaced apart from each other at regular intervals.

According to an embodiment, on the top surface of each of the first adhesive film 430 and the third adhesive film 450 to be brought into close contact with the support member 220, at least one air path may or may not be formed through which air escapes.

Referring to FIG. 6B, a first adhesive film 430 may be disposed on the other surface of a portion of the flexible printed circuit board 200 (e.g., TOP PSA body portion); a second adhesive film 440 may be disposed on the other surface of a portion of the flexible printed circuit board 200 (e.g., TOP PSA tail portion); and a third adhesive film 450 may be disposed on the other surface of a portion of the flexible printed circuit board 200 (e.g., TOP PSA tail portion).

According to an embodiment, on the top surface of the second adhesive film 440 to be brought into close contact with the support member 220, at least one air path 602 may be formed in a horizontal direction, through which air escapes. For example, on the top surface of the second adhesive film 440, a plurality of air paths 602 may be formed, and the air paths 601 may be formed to be spaced apart from each other at regular intervals.

According to an embodiment, on the top surface of each of the first adhesive film 430 and the third adhesive film 450 to be brought into close contact with the support member 220, at least one air path may or may not be formed through which air escapes.

Referring to FIG. 6C, on the other surface of the flexible printed circuit board 200, an adhesive film 430, 440, 450 may be disposed which brings the flexible printed circuit board into close contact with the support member 220 stacked toward the rear surface of the display panel. For example, a first adhesive film 430 may be disposed on the other surface of a portion of the flexible printed circuit board 200 (e.g., TOP PSA body portion); a second adhesive film 440 may be disposed on the other surface of a portion of the flexible printed circuit board 200 (e.g., TOP PSA tail portion); and a third adhesive film 450 may be disposed on the other surface of a portion of the flexible printed circuit board 200 (e.g., TOP PSA tail portion).

According to an embodiment, on the top surface of the second adhesive film 440 to be brought into close contact with the support member 220, at least one air path 601 may be formed in a vertical direction, through which air escapes, and at least one air path 602 may be formed in a horizontal direction, through which air escapes. For example, on the top surface of the second adhesive film 440, a plurality of air paths may be formed, and the air paths may be formed to be spaced apart from each other at regular intervals.

According to an embodiment, on the top surface of each of the first adhesive film 430 and the third adhesive film 450 to be brought into close contact with the support member 220, at least one air path may or may not be formed through which air escapes.

The display panel 10 according to an embodiment of the present specification may include a support member 220 stacked toward the rear surface of the display panel 10, a flexible printed circuit board 200 having a portion bent toward the rear surface of the support member 220, and an adhesive film 400 attached to one surface of the flexible printed circuit board 200 so that the bent flexible printed circuit board 200 is pressed and attached to the support member 220.

Additionally, in addition to the support member 220, the flexible printed circuit board 200, and the adhesive film 400, the display panel 10 may include a cover member, a module fixing member, a functional film, and cushion layers, which are respectively disposed at locations where they can exert their functions.

According to an embodiment, a portion of the flexible printed circuit board may be bent toward and attached to a rear surface of a support member by a first pusher (e.g., divider).

According to an embodiment, the bent flexible printed circuit board may be pressed and attached to the support member by a second pusher (not shown).

According to an embodiment, the adhesive film may have at least one air path formed on one surface thereof attached to the support member so that air is discharged during a process of pressing and attaching the flexible printed circuit board to the support member.

According to an embodiment, the adhesive film may have a plurality of air paths formed in a direction horizontal to a tail portion direction (to be specific, an extension direction of the tail portion) of the flexible printed circuit board.

According to an embodiment, the adhesive film may have a plurality of air paths formed in a direction vertical to a tail portion direction of the flexible printed circuit board.

According to an embodiment, the adhesive film may have a plurality of air paths formed in a direction horizontal to a tail portion direction of the flexible printed circuit board, and have a plurality of air paths formed in a direction vertical to the tail portion direction of the flexible printed circuit board.

The display device 100 according to an embodiment of the present specification may include a display panel including a plurality of pixels, each of which includes a plurality of sub-pixels, a data driving part transmitting a data voltage to each of the plurality of sub-pixels, and a gate driving part transmitting a gate signal to each of the plurality of sub-pixels.

And the display panel may include a support member stacked toward a rear surface of the display panel, a flexible printed circuit board having a portion bent toward the rear surface of the support member, and an adhesive film attached to one surface of the flexible printed circuit board so that the bent flexible printed circuit board is pressed and attached to the support member.

And the adhesive film may have at least one air path formed on one surface thereof attached to the support member so that air is discharged during a process of pressing and attaching the flexible printed circuit board to the support member.

As described above, since the display panel according to the present specification presses and attaches the flexible printed circuit board to the support member through the adhesive film with at least one air path formed on one surface so that air is discharged during a process of pressing and attaching the flexible printed circuit board to the support member, it is possible to alleviate defects caused by air traps that occur when the liner of the protective film is delaminated during the bending process.

Further embodiments are described below.

Referring to FIGS. 1 and 3A-3C , a display device includes a display panel 10 including a plurality of pixels. A support member 220 is disposed at a rear surface of the display panel 10. As shown in FIGS. 2B and 3A, a flexible printed circuit board 200 is electrically connected to the display panel and includes a tail portion bent onto the support member 220. An adhesive film 400 is disposed between the tail portion of the flexible printed circuit board 200 and the support member 220. The adhesive film 400 bonds the flexible printed circuit board 200 to the support member 220. At least one air path 501, 503 is formed on a surface of the adhesive film and extends between the flexible printed circuit board 200 and the support member 220. The at least one air path is configured to discharge air located between the flexible printed circuit board 200 and the support member (220), as shown in FIG. 5.

As illustrated in FIG. 6A, in some embodiments, the at least one air path 601 includes a plurality of air paths formed in a direction vertical to an extension direction of the tail portion of the flexible printed circuit board 200.

As illustrated in FIG. 6B, in some embodiments, the at least one air path 602 includes a plurality of air paths formed in a direction horizontal to an extension direction of the tail portion of the flexible printed circuit board 200.

As illustrated in FIG. 6C, in some embodiments, the at least one air path includes a first plurality of air paths 601 formed in a direction vertical to the extension direction of the tail portion of the flexible printed circuit board 200 and a second plurality of air paths 602 formed in a direction horizontal to the extension direction of the tail portion of the flexible printed circuit board 200.

Referring to FIG. 5, the at least one air path 501 may be formed on a first surface of the adhesive film that is attached to the support member 220.

Further referring to FIG. 5, the at least one air path 503 may be formed on a second surface of the adhesive film that is attached to the flexible printed circuit board 200.

As shown in FIGS. 6A -6C, the at least one air path 601, 602 may include a plurality of air paths arranged at uniform spacing along the adhesive film.

Referring again to FIG. 5, the at least one air path 501, 503 defines an air channel 502, 504 configured to guide air out from between the adhesive film and the support member 220 based on the tail portion of the flexible printed circuit board 200 being pressed toward the support member 220.

As shown in FIG. 4B, the adhesive film may include a first adhesive film disposed at a body portion of the flexible printed circuit board 200 and a second adhesive film disposed at the tail portion of the flexible printed circuit board 200, wherein the at least one air path is formed in the second adhesive film 440. While the embodiments of the present specification have been described in detail with reference to the accompanying drawings, it should be understood by a person skilled in the art that the present specification is not necessarily limited to the above embodiments, and the above embodiments can be practiced in various modified forms without departing from the technical idea of the present specification. Accordingly, the embodiments disclosed in the present specification are not intended to limit the technical idea of the present specification but to explain the technical idea of the present specification, and the scope of the technical idea of the present specification is not limited by these embodiments. Therefore, it should be understood that the embodiments described above are given only as an example in all respects but not for the purpose of limiting the specification.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a support member disposed at a rear surface of the display panel;
a flexible printed circuit board having a tail portion bent toward the rear surface of the support member; and
an adhesive film attached to one surface of the flexible printed circuit board so that the bent tail portion of the flexible printed circuit board is pressed and attached to the support member,
wherein the adhesive film includes at least one air path formed on a surface of the adhesive film that is attached to the support member so that air between the flexible printed circuit board and the support member is dischargeable.

2. The display panel of claim 1, wherein the adhesive film has a plurality of air paths formed in a direction horizontal to an extension direction of the tail portion of the flexible printed circuit board.

3. The display panel of claim 1, wherein the adhesive film has a plurality of air paths formed in a direction vertical to an extension direction of the tail portion of the flexible printed circuit board.

4. The display panel of claim 1, wherein the adhesive film has a plurality of air paths formed in a direction horizontal to an extension direction of the tail portion of the flexible printed circuit board, and has a plurality of air paths formed in a direction vertical to the extension direction of the tail portion of the flexible printed circuit board.

5. The display panel of claim 1, wherein the tail portion of the flexible printed circuit board is bent toward and attached to the rear surface of the support member.

6. The display panel of claim 1, wherein the bent tail portion of the flexible printed circuit board is pressed against and attached to the support member.

7. The display panel of claim 1, wherein the air path is formed to be concave from one end to another end of the adhesive film so that air is discharged.

8. A display device comprising:
a display panel including a plurality of pixels, each of which includes a plurality of sub-pixels;
a data driving part configured to transmit a data voltage to each of the plurality of sub-pixels; and
a gate driving part configured to transmit a gate signal to each of the plurality of sub-pixels,
wherein the display panel includes:
a support member disposed at a rear surface of the display panel;
a flexible printed circuit board having a tail portion bent toward the rear surface of the support member; and
an adhesive film attached to one surface of the flexible printed circuit board so that the bent tail portion of the flexible printed circuit board is pressed and attached to the support member,
wherein at least one first air path is formed on one side of the adhesive film to allow air existing between the support member and the adhesive film to be discharged.

9. The display device of claim 8, wherein the at least one first air path comprises a plurality of air paths formed in a direction either horizontal or vertical to an extension direction of the tail portion of the flexible printed circuit board.

10. The display device of claim 8, further comprising at least one second air path formed on the other side of the adhesive film to allow air existing between the portion of the flexible printed circuit board and the adhesive film to be discharged.

11. The display device of claim 10, wherein the at least one the second air path comprises a plurality of air paths formed in a direction either horizontal or vertical to an extension direction of the tail portion of the flexible printed circuit board.

12. A display device comprising:
a display panel including a plurality of pixels;
a support member disposed at a rear surface of the display panel;
a flexible printed circuit board electrically connected to the display panel and including a tail portion bent onto the support member;
an adhesive film disposed between the tail portion of the flexible printed circuit board and the support member, the adhesive film configured to bond the flexible printed circuit board to the support member; and
at least one air path formed on a surface of the adhesive film and extending between the flexible printed circuit board and the support member, the at least one air path configured to discharge air located between the flexible printed circuit board and the support member.

13. The display device of claim 12, wherein the at least one air path comprises a plurality of air paths formed in a direction horizontal to an extension direction of the tail portion of the flexible printed circuit board.

14. The display device of claim 12, wherein the at least one air path comprises a plurality of air paths formed in a direction vertical to an extension direction of the tail portion of the flexible printed circuit board.

15. The display device of claim 12, wherein the at least one air path comprises a first plurality of air paths formed in a direction horizontal to an extension direction of the tail portion of the flexible printed circuit board and a second plurality of air paths formed in a direction vertical to the extension direction of the tail portion of the flexible printed circuit board.

16. The display device of claim 12, wherein the at least one air path is formed on a first surface of the adhesive film that is attached to the support member.

17. The display device of claim 16, wherein the at least one air path is formed on a second surface of the adhesive film that is attached to the flexible printed circuit board.

18. The display device of claim 12, wherein the at least one air path comprises a plurality of air paths arranged at uniform spacing.

19. The display device of claim 12, wherein the at least one air path defines an air channel configured to guide air out from between the adhesive film and the support member based on the tail portion of the flexible printed circuit board being pressed.

20. The display device of claim 12, wherein the adhesive film comprises a first adhesive film disposed at a body portion of the flexible printed circuit board and a second adhesive film disposed at the tail portion, and wherein the at least one air path is formed in the second adhesive film.
